(19) United States
(12) Patent Application Publication
(10) Pub. No.: US 2021/0306780 A1
(43) Pub. Date: Sep. 30, 2021

(54) SYSTEM AND METHOD FOR AUDIO OUTPUT DEVICE TESTING

(71) Applicant: LIQUIDITY SERVICES, INC., Bethesda, MD (US)

(72) Inventors: Kristopher SCHOBERT, Garland, TX (US); Brian JOHNSON, Garland, TX (US); Calvin NANCE, Rockwall, TX (US); Anhquan NGUYEN, Garland, TX (US); Joshua MATHEW, Carrollton, TX (US); Michael SIMPSON, Allen, TX (US)

(21) Appl. No.: 16/829,522

(22) Filed: Mar. 25, 2020

(51) Int. Cl. H04R 29/00; G01R 31/28

(52) U.S. Cl. CPC H04R 29/001; G01R 31/2872

(57) ABSTRACT

Systems, methods, apparatuses, and computer program products for audio output device testing. For example, some embodiments described herein may provide for audio output device testing in an objective and consistent manner Specifically, some embodiments may provide a system that can be used to determine an array of tests for an audio output device, cause the audio output device to be tested according to the array of tests, compare a performance of the audio output device to a baseline performance, and intelligently and objectively determine a score for the audio output device. In addition, the system may trigger, or perform, certain actions with respect to the audio output device based on the score.

### FIELD

Some example embodiments may generally relate to testing audio output devices. For example, certain embodiments may relate to systems and methods for audio output device testing.

### BACKGROUND

Headphones, as one example of an audio output device, may include a pair of small loudspeaker drivers worn on or around the head of a user's ears. These devices may be electroacoustic transducers, which may convert an electrical signal to a corresponding sound. Headphones may be circumaural (around the ear) or supra-aural (over the ear). Headphones may use a band over the top of the head to hold the speakers in place. Other types of headphones may include earbuds or earpieces that are inserted into the user's ear canal or may include bone conduction headphones, which typically wrap around the back of the head and rest in front of the ear canal, leaving the ear canal open. Other audio output devices may include speakers.

### SUMMARY

According to a first embodiment, a method may include determining a wireless address of a device under testing (DUT). The DUT may be an audio output device. The method may include determining an array of tests for the DUT based on information associated with the DUT. The method may include providing an indication that the DUT can be placed on a testing base for testing or that the system is ready to perform the array of tests. The method may include establishing an audio connection with the DUT in association with the DUT being placed on the testing base or the system being ready to perform the array of tests. The method may include performing the array of tests by providing a set of instructions associated with causing the DUT or a speaker device of the system to output audio. The method may include determining, in association with performing the array of tests, a result of the array of tests.

In a variant, the method may further include receiving, prior to determining the wireless address, a portion of the information associated with the DUT from a reader device of the system. The portion of the information may be from a tag associated with the DUT. The method may further include determining another portion of the information from a database based on the portion of the information from the tag. In a variant, the method may include providing, for display, a set of instructions associated with causing the DUT to be moved into communicative proximity of a near-field communication (NFC) device prior to determining the wireless address of the DUT. In a variant, determining the wireless address may include determining the wireless address via the NFC device after providing the set of instructions for display

In a variant, the information associated with the DUT may identify at least one of a make of the DUT, a model of the DUT, an age of the DUT, a capability of the DUT, a quantity of hours of audio output of the DUT, or an amount of time since the DUT was subject to a particular test. In a variant, establishing the connection may comprise at least one of providing the wireless address and a set of instructions to a transceiver of the system. The set of instructions may be associated with causing the transceiver to establish a wireless connection with the DUT using the wireless address. In a variant, the method may include actuating a robotic arm of the system to cause an audio cable to be coupled with an audio jack of the DUT to establish a wired connection with the DUT.

In a variant, the array of tests may include at least one of a test of a volume range of the DUT, a test of a frequency range of the DUT, a test of whether speakers of the DUT are operational, a test of a button or other control of the DUT, a test of a mechanical hinge, swivel, or adjuster of the DUT, a test of a power jack of the DUT, or a test of an audio jack of the DUT. In a variant, performing the array of tests may further comprise providing another set of instructions associated with causing the DUT to operate in a particular mode based on whether the set of instructions is associated with causing the DUT or the speaker device to output audio. In a variant, performing the array of tests may comprise providing the set of instructions to cause the DUT or the at least one speaker device to output the audio at a particular frequency range or volume. In a variant, the particular mode may comprise at least one of a noise canceling mode, an ambient sound mode, or a bass boosting mode.

In a variant, determining the result of the array of tests may comprise determining a score for at least one test of the array of tests or for the DUT, and determining a pass or failure of the array of tests or the DUT based on the score. In a variant, the method may further comprise performing one or more actions based on the result of the array of tests. In a variant, the one or more actions may include at least one of providing the result for display, outputting an indication based on the result, scheduling the DUT for recycling or refurbishing, generating a report that identifies one or more components of the DUT to be recycled or refurbished, or causing the DUT to be transported to an area of a facility associated with shipping, packaging, recycling, or refurbishing the DUT.

A second embodiment may be directed to an apparatus including at least one processor and at least one memory comprising computer program code. The at least one memory and computer program code may be configured, with the at least one processor, to cause the apparatus at least to perform the method according to the first embodiment, or any of the variants discussed above.

A third embodiment may be directed to an apparatus that may include circuitry configured to perform the method according to the first embodiment, or any of the variants discussed above.

A fourth embodiment may be directed to an apparatus that may include means for performing the method according to the first embodiment, or any of the variants discussed above.

A fifth embodiment may be directed to a computer readable medium comprising program instructions stored thereon for performing at least the method according to the first embodiment, or any of the variants discussed above.

A sixth embodiment may be directed to a system. The system may include one or more devices configured to perform at least the method according to the first embodiment, or any of the variants discussed above.

A seventh embodiment may be directed to a computer program product encoding instructions for performing at least the method according to the first embodiment, or any of the variants discussed above.

### BRIEF DESCRIPTION OF THE DRAWINGS

For proper understanding of example embodiments, reference should be made to the accompanying drawings, wherein:

FIG. 1 illustrates an example system for audio output device testing;

FIG. 2 illustrates example operations of the example system of FIG. 1;

FIG. 3 illustrates an example flow diagram of a method, according to some embodiments; and

FIG. 4 illustrates an example block diagram of an apparatus, according to an embodiment.

### DETAILED DESCRIPTION

It will be readily understood that the components of certain example embodiments, as generally described and illustrated in the figures herein, may be arranged and designed in a wide variety of different configurations. Thus, the following detailed description of some example embodiments of systems, methods, apparatuses, and computer program products for audio output device testing is not intended to limit the scope of certain embodiments but is representative of selected example embodiments.

The features, structures, or characteristics of example embodiments described throughout this specification may be combined in any suitable manner in one or more example embodiments. For example, the usage of the phrases “certain embodiments,” “some embodiments,” or other similar language, throughout this specification refers to the fact that a particular feature, structure, or characteristic described in connection with an embodiment may be included in at least one embodiment. Thus, appearances of the phrases “in certain embodiments,” “in some embodiments,” “in other embodiments,” or other similar language, throughout this specification do not necessarily all refer to the same group of embodiments, and the described features, structures, or characteristics may be combined in any suitable manner in one or more example embodiments.

Additionally, if desired, the different functions or operations discussed below may be performed in a different order and/or concurrently with each other. Furthermore, if desired, one or more of the described functions or operations may be optional or may be combined. As such, the following description should be considered as merely illustrative of the principles and teachings of certain example embodiments, and not in limitation thereof.

Audio output devices (e.g., headphones, speakers, and/or the like) may be tested to determine whether the audio output devices are operational and/or to determine operational limits of the audio output devices. These tests have been performed using human testers, where the human testers listen to audio output from the devices to determine success or failure of the devices for an array of tests. Due to the use of human testers, these tests are subject to significant variability because of variations in hearing ability and the subjectivity of the human testers, which results in lower quality test results, significant occurrence of false positive or false negative outcomes, and/or the like. These negative impacts of using human testers causes resources to be wasted shipping and/or replacing faulty audio output devices, increased testing time, missed opportunities for recycling non-faulty electrical and mechanical components from faulty devices, inadvertent disposal of non-faulty electrical and mechanical components, and/or the like. As such, there is a need for systems and methods that objectively and consistently test audio output devices with a higher quality and a faster speed than human testers.

Some embodiments described herein may provide for audio output device testing in an objective and consistent manner. For example, some embodiments described herein may provide a system that can be used to determine an array of tests for an audio output device, cause the audio output device to be tested according to the array of tests, compare a performance of the audio output device to a baseline performance, and intelligently and objectively determine a score for the audio output device. In addition, the system may trigger, or perform, certain actions with respect to the audio output device based on the score. In this way, some embodiments described herein may provide for more objective and consistent testing of audio output devices, which improves a quality and speed of the testing. This conserves resources that would otherwise be wasted through inaccurate testing.

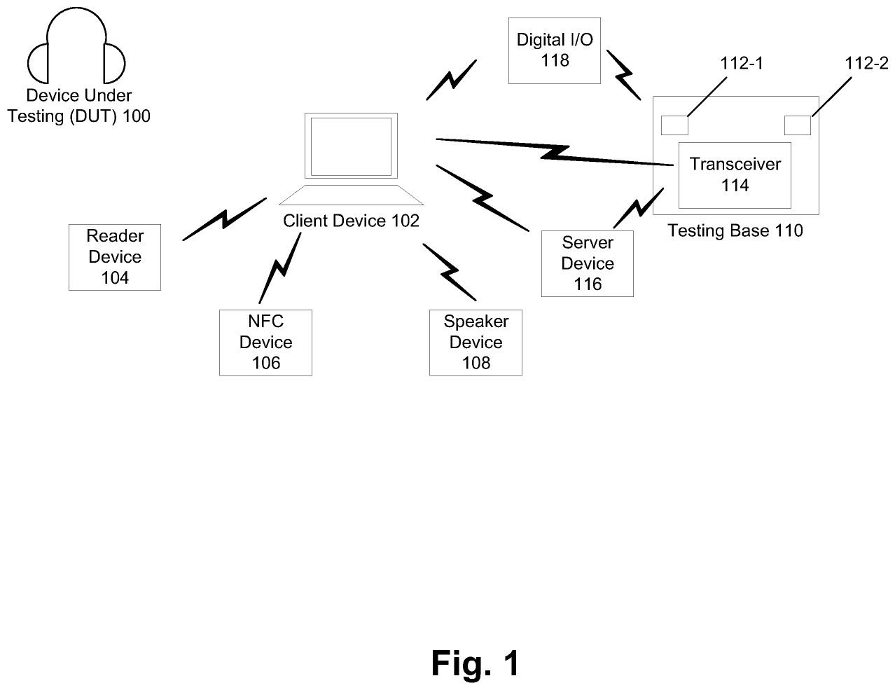

FIG. 1 illustrates an example system for audio output device testing, according to some embodiments. FIG. 1 illustrates a device under testing (DUT) 100 and a system for testing the DUT 100. The system may include a client device 102. In addition, the system may include, connected to the client device 102, a reader device 104, a near field communication (NFC) device 106, and a speaker device 108. Further, the system may include a testing base 110, which may be a mechanical apparatus that may provide mechanical support to one or more other devices. Specifically, in some embodiments, the testing base 110 may include microphones 112-1 and 112-2 connected to a transceiver 114, where the transceiver 114 may be connected to the client device 102. In addition, the system may include a server device 116 connected to the transceiver 114. A digital input/output (digital I/O) 118 may be connected to the microphones 112-1 and 112-2, and to the client device 102.

The DUT 100 may include one or more audio output devices capable of receiving a wired or wireless signal and outputting audio. With respect to some embodiments described herein, DUT 100 may be a pair of headphones. However, in other embodiments, DUT 100 may include another audio output device, such as one or more speakers. In some embodiments, the DUT 100 may receive a wired or wireless signal from transceiver 114, or another element of the system, and may output audio to microphones 112-1, 112-2, as described elsewhere herein. Additionally, or alternatively, the DUT 100 (or a component thereof) may be connected to NFC device 106 to provide client device 102 with, for example, a Bluetooth address of the DUT 100 so that client device 102 can instruct transceiver 114 to connect to the DUT 100, as described elsewhere herein.

The client device 102 may include one or more devices capable of coordinating operations of one or more other devices, accessing information in a database, displaying information from the database, causing a test of the DUT 100 to be performed, and/or the like. For example, the client device 102 may include a laptop computer, a desktop computer, a mobile device (e.g., a smartphone or a tablet), and/or the like. In some embodiments, the client device 102 may determine an array of tests for the DUT 100 based on information from the reader device 104 or stored in a database, and may cause the speaker device 108 and/or the transceiver 114 to perform the array of tests, as described elsewhere herein. Additionally, or alternatively, the client device 102 may provide, for display, information related to the DUT 100, a result of the array of tests, and/or the like, as described elsewhere herein.

The reader device 104 may include one or more devices capable of reading a tag, such as a barcode, a QR code, an RFID tag, and/or the like. For example, the reader device 104 may include a barcode reader, a quick response (QR) code reader, a radio frequency identifier (RFID) reader, and/or the like. In some embodiments, the reader device 104 may read a tag associated with the DUT 100 (e.g., prior to testing of the DUT 100), as descried elsewhere herein. Additionally, or alternatively, the reader device 104 may provide information stored by the tag (e.g., an identifier of the DUT 100) to the client device 102 so that the client device 102 can identify information in a database related to the DUT 100, as described elsewhere herein.

The NFC device 106 may include one or more devices capable of using short-range wireless communication protocols, such as NFC. For example, NFC device 106 may be an NFC reader, a Bluetooth low energy (BLE) reader, and/or the like. In some embodiments, the NFC device 106 may connect with the DUT 100 to obtain information from the DUT 100 that can be used to connect to the DUT 100 for testing (e.g., a Bluetooth, or other wireless address, of the DUT 100), as described elsewhere herein.

The speaker device 108 may include one or more devices capable of outputting audio in association with a test of the DUT 100. For example, the speaker device 108 may include a speaker (e.g., a Bluetooth speaker) and one or more components configured to control output from the speaker. In some embodiments, the speaker device 108 may receive a set of commands and/or data from the client device 102 that causes the speaker device 108 to output audio at a set of volumes, at a set of frequencies, from a set of directions relative to the DUT 100, and/or the like in association with a test of the DUT 100, as described elsewhere herein. Since the speaker device 108 may be used to test various external noise-related modes of the DUT 100 (e.g., noise cancelling or ambient sound boosting), the speaker device 108 may output a baseline sound (e.g., at a particular volume and/or frequency) prior to activation of an external noise-related mode. In this case, the microphones 112 may receive this baseline sound and the system may record it for comparison after activation of the external noise-related mode of the DUT 100.

As described above, the testing base 110 may include a structural apparatus that can be used during testing of the DUT 100. For example, the testing base 110 may be configured such that it can support the DUT 100 during a test such that right and left speakers of the DUT 100 are positioned to play audio output into the microphones 112-1 and 112-2, respectively. Additionally, or alternatively, the testing base 110 may be configured such that audio from one speaker of DUT 100 does not interfere with audio from another speaker of the DUT 100. For example, the testing base 110 may include one or more structures to form-fit cups or earpieces of the DUT 100, may include sound proofing between microphones 112-1 and 112-2, and/or the like.

The microphones 112 may include one or more devices capable of functioning as a transducer to convert sound into an electrical signal. For example, a microphone 112 may include a dynamic microphone that uses a coil or wire suspended in a magnetic field, a condenser microphone that uses a vibrating diaphragm as a capacitor plate, a piezoelectric microphone that uses a crystal of piezoelectric material, and/or the like. In some embodiments, a microphone 112 may receive audio output from DUT 100, may convert the audio output into an electrical signal, and may provide the electrical signal to the client device 102 and/or to the transceiver 114, and/or the like.

The transceiver 114 may include one or more devices capable of transmitting or receiving a signal. For example, the transceiver 114 may include a separate receiver and transmitter, or a combined receiver and transmitter. In some embodiments, the transceiver 114 may receive commands and/or data from the client device 102 and may cause the DUT 100 to output audio for a test based on the commands and/or the data, as described elsewhere herein. Additionally, or alternatively, the transceiver 114 may receive electrical signals from the microphones 112 and may provide data related to the electrical signals to the server device 116 for processing, as described elsewhere herein.

The server device 116 may include one or more devices capable of processing data related to output from the DUT 100. For example, the server device 116 may include a server in a datacenter, a set of cloud-based applications hosted on a server, and/or the like. In some embodiments, the server device 116 may receive data related to output from the DUT 100, may process the data to determine a result of the testing of the DUT 100, may store the result in a database, and/or the like, as described elsewhere herein. Additionally, or alternatively, the server device 116 may generate a report related to the result of the test, and may provide the report and/or the result for display via the client device 102, as described elsewhere herein. For example, the report may include information that identifies a result of a test, a score for the test or the DUT 100, whether the test or the DUT 100 has passed or failed, and/or the like.

The digital I/O 118 may include one or more devices or circuits configured to convert an electrical signal to a digital signal. For example, and as described elsewhere herein, the digital I/O 118 may receive an electrical signal from a microphone 112 (corresponding to sound detected from the DUT 100) and may convert the electrical signal to a digital signal. The digital I/O 118 may output the digital signal to the client device 102 for processing, as described elsewhere herein.

The system may include additional devices or fewer devices than those illustrated in and described with respect to FIG. 1. In addition, the connections illustrated in and described with respect to FIG. 1 may be wireless connections, wired connections, or a combination of wired and wireless connections.

As described above, FIG. 1 is provided as an example. Other examples are possible, according to some embodiments.

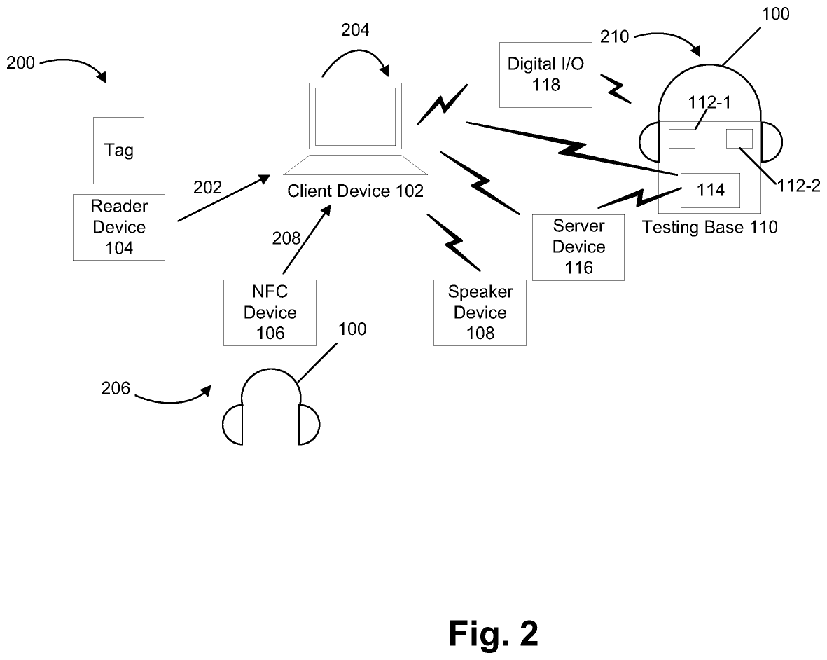

FIG. 2 illustrates example operations of the example system of FIG. 1, according to some embodiments. For example, FIG. 2 illustrates operations related testing the DUT 100.

As illustrated at 200, a tag associated with the DUT 100 may be placed within communicative proximity of the reader device 104 to so that the reader device 104 can read the tag. For example, the tag may be on a packaging of the DUT 100, may be on the DUT 100, and/or the like and may be associated with inventory management operations related to the DUT 100. As illustrated at 202, after reading the tag, the reader device 104 may provide, to the client device 102, information stored by the tag. For example, the information may identify the DUT 100, may identify a make or a model of the DUT 100, an inventory record of the DUT 100, an age of the DUT 100, and/or the like.

As illustrated at 204, after receiving the information from the reader device 104, the client device 102 may process the information. For example, the client device 102 may identify a set of records associated with the DUT 100 in a database. The set of records may identify a make or a model of the DUT 100, an age of the DUT 100, an array of tests previously performed for the DUT 100, a date of the previous array of tests, a result of the previous array of tests, and/or the like. The client device 102 may provide, for display via a display associated with the client device 102, information read from the tag, information from the database, and/or the like. Additionally, or alternatively, the client device 102 may provide, for display, a set of instructions related to testing the DUT 100. For example, the client device 102 may provide, for display, a next step in testing the DUT 100 (e.g., an instruction to move the DUT 100 within communicative proximity of the NFC device 106).

As illustrated at 206, the DUT 100 may be moved within communicative proximity of the NFC device 106. For example, the DUT 100 may be moved within communicative proximity of the NFC device 106 such that a short-range wireless connection is formed between the DUT 100 and the NFC device 106. The NFC device 106 may receive information from the DUT 100 via this wireless connection. For example, the information may identify a wireless address (e.g., a Bluetooth address) of the DUT 100, a quantity of hours of audio output from the DUT 100, a model and/or make of the DUT 100, a model and/or make of components of the DUT 100, features of the DUT 100 (e.g., in the case where DUT 100 is a pair of headphones, the features may include whether the DUT 100 has noise cancelling capabilities, bass boosting capabilities, ambient sound capabilities, and/or the like), and/or the like. As illustrated at 208, the NFC device 106 may provide, to the client device 102, the information received from the DUT 100 after receiving the information from the DUT 100. The client device 102 may provide, for display, this information after receiving the information, may update the set of instructions provided for display to a next step, and/or the like.

The client device 102 may determine an array of tests to perform on the DUT 100. For example, the client device 102 may determine the array of tests after receiving the information from the NFC device 106, after identifying the set of records in the database related to the DUT 100, and/or the like. In some embodiments, the client device 102 may determine the array of tests based on the make and/or the model of the DUT 100 (e.g., certain tests may be associated with certain makes and/or models of DUTs 100). Additionally, or alternatively, the client device 102 may determine the array of tests based on an age of the DUT 100 and/or a date of a previous array of tests performed on the DUT 100 (e.g., certain tests may be scheduled to be performed at an interval or at a particular age of the DUT 100).

Additionally, or alternatively, the client device 102 may determine the array of tests intelligently using machine learning or artificial intelligence. For example, the client device 102 may process information from the tag, information stored in the database, and/or the like using a machine learning or artificial intelligence model where output from the model identifies an array of tests to be performed for the DUT 100 based on various criteria or factors associated with the DUT 100 (e.g., a make and/or model of the DUT 100, an age of the DUT 100, a quantity of hours of audio output of the DUT 100, and/or the like).

The client device 102 may provide, for display, information that identifies the array of tests after determining the array of tests. Additionally, or alternatively, the client device 102 may determine an order in which the array of tests is to be performed. For example, certain tests may have to be passed before certain other tests can be performed. Additionally, or alternatively, and as another example, some tests can be simplified based on results of prior test (e.g., if output capabilities of the DUT 100 are tested via a wireless connection by testing different volume levels and/or frequency levels, then a subsequent test of a cord-based audio jack may not have to include different volume or frequencies tests). This may conserve resources associated with testing by reducing or eliminating performance of tests that would be inaccurate or not capable of being performed based on results of other tests.

The array of tests may be particular to the DUT 100. For example, for headphones as the DUT 100, the array of tests may include a test of a frequency range of the speakers of the DUT 100, a volume range of the DUT 100, whether the speakers of the DUT 100 are operational, an operation of a mode or a capability of the DUT 100 (e.g., a noise canceling mode or capability, an ambient noise mode or capability, or a bass boosting mode or capability), and/or the like. Additionally, or alternatively, for a pair of headphones as the DUT 100, the array of tests may include a test of a button or other control (e.g., a touch control), a folding mechanism, a swivel mechanism, an adjustment mechanism (e.g., a headband adjustment mechanism), an input/output jack, a power jack (e.g., by testing wither a power cable draws power), and/or the like.

The client device 102 may determine reference data for the array of tests. For example, the client device 102 may determine reference audio waveforms for each of the tests to which data gathered by the microphones 112 may be compared to determine a success or failure of the test, to determine operation of the DUT 100, and/or the like.

As illustrated at 210, the DUT 100 may be mounted on testing base 110 after providing information to the NFC device 106. For example, the DUT 100 may be positioned on the testing base 110 such that a left speaker of the DUT 100 is aligned with the microphone 112-1 and the right speaker of the DUT 100 is aligned with the microphone 112-2. Additionally, or alternatively, the DUT 100 may be mounted on the testing base 110 such that mechanical components of the DUT 100 are aligned with mechanical and/or robotic elements of the testing base 110. For example, a power or audio jack of the DUT 100 may be aligned with a power cable head or an audio cable jack (or a robotic element securing the power cable or the audio jack), a robotic arm that can press a button of the DUT 100, and/or the like.

The client device 102 may activate an indicator, such as a light, a speaker, and/or the like, to indicate to place the DUT 100 on the testing base 110, that the DUT 100 has been properly placed on the testing base 110, and/or the like. The client device 102 may provide, for display, instructions to secure the DUT 100, to show how the DUT 100 is to be placed on the testing base 110, and/or the like, and/or may update instructions provided for display.

After placement of the DUT 100 on the testing base 110, the client device 102 may initiate the array of tests of the DUT 100. For example, the client device 102 may provide a set of instructions and/or data to the transceiver 114 related to causing the transceiver 114 to connect to the DUT 100 and to causing the DUT 100 to output audio. Continuing with the previous example, the transceiver 114 may similarly provide instructions (e.g., hex commands) and/or data to the DUT 100 to cause the DUT 100 to output audio at different volume levels, different frequency levels, from the left or right speakers separately or in combination, and/or the like, in association with performing one or more tests of the DUT 100.

Additionally, or alternatively, the client device 102 may provide instructions and/or data to the speaker device 108 related to causing the speaker device 108 to output audio in association with performing a test of the DUT 100. For example, the speaker device 108 may output audio at particular volumes or frequencies. The client device 102 may activate an indicator associated with the testing base 110 to indicate that the array of tests are being performed, to indicate a particular test that is being performed, to indicate a pass or fail of a test, and/or the like. Additionally, or alternatively, the client device 102 may provide, for display, information that indicates a pass or a failure of a test, may provide data related to a test (e.g., a comparison of expected data and actual data related to output from the DUT 100), and/or the like.

The transceiver 114 may also provide, to the DUT 100, instructions to cause the DUT 100 to operate in a particular mode. For example, when DUT 100 is tested based on audio output from the speaker device 108, the instructions may cause the DUT 100 to activate an ambient sound mode, a noise canceling mode, and/or the like. Additionally, or alternatively, and as another example, when output from the DUT 100 is being tested, the transmitter 114 may provide instructions to the DUT 100 to operate in a bass boosting mode.

The microphones 112 may receive audio from the DUT 100 and/or an ambient environment of the DUT 100 and may convert the audio to electrical signals that are then sent to the digital I/O 118. The digital I/O 118 may convert the electrical signals to digital signals and may send the digital signals to the client device 102. The digital I/O 118 (or the client device 102) may transmit data associated with the electrical signals to the server device 116. For example, the data may identify characteristics of the audio based on the electrical signals from the microphones 112. Additionally, or alternatively, and as another example, the server device 116 may determine whether buttons and/or jacks/ports associated with the DUT 100 are operational, whether the DUT 100 has withstood certain mechanical stresses and/or movements, and/or the like in the case of a test of various mechanical functionalities of the DUT 100.

The server device 116 or the client device 102 may process the data related to the audio received by the microphones 112 to determine a result of the array of tests. For example, the server device 116 or the client device 102 may determine whether the DUT 100 has output audio at a particular frequency or volume level (e.g., a threshold frequency or volume level, an expected frequency or volume level, and/or the like), whether both the left and the right speakers of the DUT 100 are operational, and/or the like in the case of a test of output from the DUT 100. Additionally, or alternatively, and as another example, the server device 116 or the client device 102 may determine whether a threshold amount of external noise received by the microphones 112 in the case of testing external noise-related modes of DUT 100, such as a noise canceling mode or an ambient sound mode.

The server device 116 or the client device 102 may determine a score for each test and/or for the DUT 100 based on a result of the testing. For example, the server device 116 or the client device 102 may determine the score based on whether the results satisfied certain thresholds, data values obtained as results, whether results were obtained, and/or the like. Additionally, or alternatively, the server device 116 may determine the score based on weights or priorities associated the various tests. In some embodiments, the server device 116 may use machine learning or artificial intelligence to determine the score. For example, the server device 116 or the client device 102 may use a machine learning model or an artificial intelligence model to process results of the various tests to determine a score for each of the tests and/or for the DUT 100. In some embodiments, the server device 116 may generate a report and may output the report and/or the score for display via the client device (e.g., by sending a message to the client device 102, by updating a record in a database that is used to populate a user interface provided for display via the client device 102, and/or the like).

In some embodiments, the system of FIG. 1 may perform various actions based on the report and/or the score. For example, the system may activate an alarm (e.g., a light or a sound) to indicate the score, to indicate a pass or a failure of the tests, and/or the like. Additionally, or alternatively, the system may schedule further tests for the DUT 100 or may schedule processing of the DUT 100 (e.g., recycling, refurbishing, or packaging along with generating a report of which components of the DUT 100 can be recycled or which may have to be replaced in the case of recycling or refurbishing) based on the score and/or based on results of certain tests. Additionally, or alternatively, the system may provide instructions to a robotic apparatus or another factory machine to remove the DUT 100 from the testing base 110, to place the DUT 110 on a conveyor belt or cart to transport the DUT 100 to a particular location of a facility for storage and/or processing, and/or the like.

As indicated above, FIG. 2 is provided as an example. Other examples are possible, according to some embodiments.

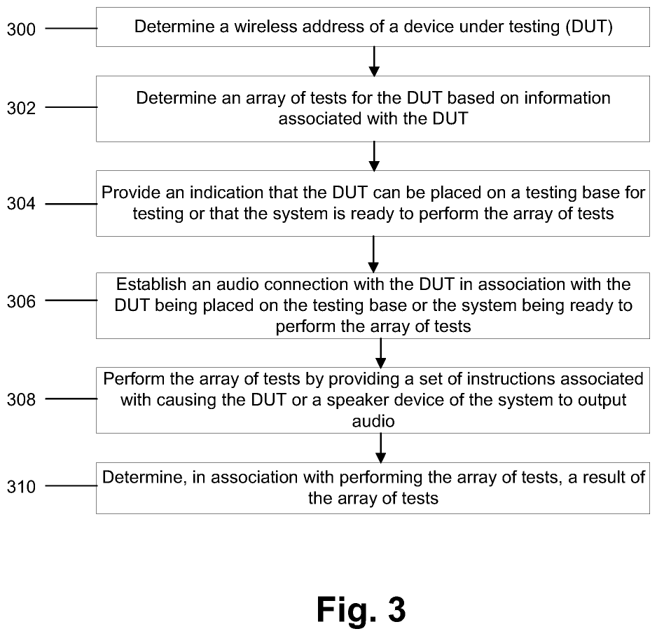

FIG. 3 illustrates an example flow diagram of a method, according to some embodiments. For example, FIG. 3 shows example operations of the example system of FIG. 1. Some of the operations illustrated in FIG. 3 may be similar to some operations shown in, and described with respect to, FIGS. 1-2.

In an embodiment, the method may include, at 300, determining a wireless address of a device under testing (DUT). The DUT may be an audio output device. In an embodiment, the method may include, at 302, determining an array of tests for the DUT based on information associated with the DUT. In an embodiment, the method may include, at 304, providing an indication that the DUT can be placed on a testing base for testing or that the system is ready to perform the array of tests. In an embodiment, the method may include, at 306, establishing an audio connection with the DUT in association with the DUT being placed on the testing base or the system being ready to perform the array of tests. In an embodiment, the method may include, at 308, performing the array of tests by providing a set of instructions associated with causing the DUT or a speaker device of the system to output audio. In an embodiment, the method may include, at 310, determining, in association with performing the array of tests, a result of the array of tests.

In some embodiments, the method may further include receiving, prior to determining the wireless address, a portion of the information associated with the DUT from a reader device of the system. The portion of the information may be from a tag associated with the DUT. The method may further include determining another portion of the information from a database based on the portion of the information from the tag. In some embodiments, the method may include providing, for display, a set of instructions associated with causing the DUT to be moved into communicative proximity of a near-field communication (NFC) device prior to determining the wireless address of the DUT. In some embodiments, determining the wireless address may include determining the wireless address via the NFC device after providing the set of instructions for display.

In some embodiments, the information associated with the DUT may identify at least one of a make of the DUT, a model of the DUT, an age of the DUT, a capability of the DUT, a quantity of hours of audio output of the DUT, or an amount of time since the DUT was subject to a particular test. In some embodiments, establishing the connection may comprise at least one of providing the wireless address and a set of instructions to a transceiver of the system. The set of instructions may be associated with causing the transceiver to establish a wireless connection with the DUT using the wireless address. In some embodiments, the method may include actuating a robotic arm of the system to cause an audio cable to be coupled with an audio jack of the DUT to establish a wired connection with the DUT.

In some embodiments, the array of tests includes at least one of a test of a volume range of the DUT, a test of a frequency range of the DUT, a test of whether speakers of the DUT are operational, a test of a button or other control of the DUT, a test of a mechanical hinge, swivel, or adjuster of the DUT, a test of a power jack of the DUT, or a test of an audio jack of the DUT. In some embodiments, performing the array of tests further comprises providing another set of instructions associated with causing the DUT to operate in a particular mode based on whether the set of instructions is associated with causing the DUT or the speaker device to output audio. In some embodiments, performing the array of tests may comprise providing the set of instructions to cause the DUT or the at least one speaker device to output the audio at a particular frequency range or volume. In some embodiments, the particular mode may comprise at least one of a noise canceling mode, an ambient sound mode, or a bass boosting mode.

In some embodiments, determining the result of the array of tests may comprise determining a score for at least one test of the array of tests or for the DUT, and determining a pass or failure of the array of tests or the DUT based on the score. In some embodiments, the method may further comprise performing one or more actions based on the result of the array of tests. In some embodiments, the one or more actions may include at least one of providing the result for display, outputting an indication based on the result, scheduling the DUT for recycling or refurbishing, generating a report that identifies one or more components of the DUT to be recycled or refurbished, or causing the DUT to be transported to an area of a facility associated with shipping, packaging, recycling, or refurbishing the DUT.

As described above, FIG. 3 is provided as an example. Other examples are possible according to some embodiments.

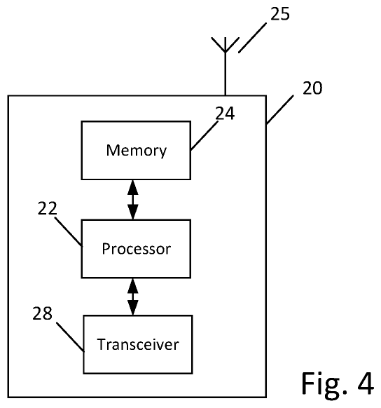

FIG. 4 illustrates an example of an apparatus 20 according to an embodiment. In an embodiment, apparatus 20 may be an element in the system illustrated in FIG. 1 and/or a DUT that interacts with the system. For example, apparatus 20 may be DUT 100, the client device 102, the reader device 104, the NFC device 106, the speaker device 108, the testing base 110, the microphone 112, the transceiver 114, the server device 116, and/or the digital I/O 118.

In some example embodiments, apparatus 20 may include one or more processors, one or more computer-readable storage medium (for example, memory, storage, or the like), one or more radio access components (for example, a modem, a transceiver, or the like), and/or a user interface. In some embodiments, apparatus 20 may be configured to operate using one or more radio access technologies, such as GSM, LTE, LTE-A, NR, 5G, WLAN, WiFi, NB-IoT, Bluetooth, NFC, MulteFire, and/or any other radio access technologies. It should be noted that one of ordinary skill in the art would understand that apparatus 20 may include components or features not shown in, or different than, FIG. 4, depending on the device to which apparatus 20 corresponds.

As illustrated in the example of FIG. 4, apparatus 20 may include or be coupled to a processor 22 for processing information and executing instructions or operations. Processor 22 may be any type of general or specific purpose processor. In fact, processor 22 may include one or more of general-purpose computers, special purpose computers, microprocessors, digital signal processors (DSPs), field-programmable gate arrays (FPGAs), application-specific integrated circuits (ASICs), and processors based on a multi-core processor architecture, as examples. While a single processor 22 is shown in FIG. 4, multiple processors may be utilized according to other embodiments. For example, it should be understood that, in certain embodiments, apparatus 20 may include two or more processors that may form a multiprocessor system (e.g., in this case processor 22 may represent a multiprocessor) that may support multiprocessing. In certain embodiments, the multiprocessor system may be tightly coupled or loosely coupled (e.g., to form a computer cluster).

Processor 22 may perform functions associated with the operation of apparatus 20 including, as some examples, precoding of antenna gain/phase parameters, encoding and decoding of individual bits forming a communication message, formatting of information, and overall control of the apparatus 20, including processes related to management of communication resources.

Apparatus 20 may further include or be coupled to a memory 24 (internal or external), which may be coupled to processor 22, for storing information and instructions that may be executed by processor 22. Memory 24 may be one or more memories and of any type suitable to the local application environment, and may be implemented using any suitable volatile or nonvolatile data storage technology such as a semiconductor-based memory device, a magnetic memory device and system, an optical memory device and system, fixed memory, and/or removable memory. For example, memory 24 can be comprised of any combination of random access memory (RAM), read only memory (ROM), static storage such as a magnetic or optical disk, hard disk drive (HDD), or any other type of non-transitory machine or computer readable media. The instructions stored in memory 24 may include program instructions or computer program code that, when executed by processor 22, enable the apparatus 20 to perform tasks as described herein.

In an embodiment, apparatus 20 may further include or be coupled to (internal or external) a drive or port that is configured to accept and read an external computer readable storage medium, such as an optical disc, USB drive, flash drive, or any other storage medium. For example, the external computer readable storage medium may store a computer program or software for execution by processor 22 and/or apparatus 20.

In some embodiments, apparatus 20 may also include or be coupled to one or more antennas 25 for receiving a signal and for transmitting another signal from apparatus 20. Apparatus 20 may further include a transceiver 28 configured to transmit and receive information. The transceiver 28 may also include a radio interface (e.g., a modem) coupled to the antenna 25. The radio interface may correspond to a plurality of radio access technologies including one or more of GSM, LTE, LTE-A, 5G, NR, WLAN, NB-IoT, Bluetooth, BT-LE, NFC, RFID, UWB, and the like. In other embodiments, apparatus 20 may include an input and/or output device (I/O device), such as a display, a button or touch control, a speaker, a microphone, a camera, and/or the like. In certain embodiments, apparatus 20 may further include a user interface, such as a graphical user interface or touchscreen.

In an embodiment, memory 24 stores software modules that provide functionality when executed by processor 22. The modules may include, for example, an operating system that provides operating system functionality for apparatus 20. The memory may also store one or more functional modules, such as an application or program, to provide additional functionality for apparatus 20. The components of apparatus 20 may be implemented in hardware, or as any suitable combination of hardware and software. According to an example embodiment, apparatus 20 may optionally be configured to communicate with apparatus 10 via a wireless or wired communications link 70 according to any radio access technology.

According to some embodiments, processor 22 and memory 24 may be included in or may form a part of processing circuitry or control circuitry. In addition, in some embodiments, transceiver 28 may be included in or may form a part of transceiving circuitry.

As used herein, the term “circuitry” may refer to hardware-only circuitry implementations (e.g., analog and/or digital circuitry), combinations of hardware circuits and software, combinations of analog and/or digital hardware circuits with software/firmware, any portions of hardware processor(s) with software (including digital signal processors) that work together to case an apparatus (e.g., apparatus 10) to perform various functions, and/or hardware circuit(s) and/or processor(s), or portions thereof, that use software for operation but where the software may not be present when it is not needed for operation. As a further example, as used herein, the term “circuitry” may also cover an implementation of merely a hardware circuit or processor (or multiple processors), or portion of a hardware circuit or processor, and its accompanying software and/or firmware. The term circuitry may also cover, for example, a baseband integrated circuit in a server, cellular network node or device, or other computing or network device.

According to certain embodiments, apparatus 20 may be controlled by memory 24 and processor 22 to perform the functions associated with example embodiments described herein. For example, in some embodiments, apparatus 20 may be configured to perform one or more of the processes described with respect to, or depicted in, FIGS. 1-3.

For instance, in one embodiment, apparatus 20 may be controlled by memory 24 and processor 22 to determine a wireless address of a device under testing (DUT). The DUT may be an audio output device. In the embodiment, apparatus 20 may be controlled by memory 24 and processor 22 to determine an array of tests for the DUT based on information associated with the DUT. In the embodiment, apparatus 20 may be controlled by memory 24 and processor 22 to provide an indication that the DUT can be placed on a testing base for testing or that the system is ready to perform the array of tests. In the embodiment, apparatus 20 may be controlled by memory 24 and processor 22 to establish an audio connection with the DUT in association with the DUT being placed on the testing base or the system being ready to perform the array of tests. In the embodiment, apparatus 20 may be controlled by memory 24 and processor 22 to perform the array of tests by providing a set of instructions associated with causing the DUT or a speaker device of the system to output audio. In the embodiment, apparatus 20 may be controlled by memory 24 and processor 22 to determine, in association with performing the array of tests, a result of the array of tests.

Therefore, certain example embodiments provide several technological improvements, enhancements, and/or advantages over existing technological processes. For example, one benefit of some example embodiments is improved accuracy and/or speed of testing an audio output device. Accordingly, the use of some example embodiments results in improved functioning of device testing and, therefore constitute an improvement at least to the technological field of device testing, among others.

In some example embodiments, the functionality of any of the methods, processes, signaling diagrams, algorithms or flow charts described herein may be implemented by software and/or computer program code or portions of code stored in memory or other computer readable or tangible media, and executed by a processor.

In some example embodiments, an apparatus may be included or be associated with at least one software application, module, unit or entity configured as arithmetic operation(s), or as a program or portions of it (including an added or updated software routine), executed by at least one operation processor. Programs, also called program products or computer programs, including software routines, applets and macros, may be stored in any apparatus-readable data storage medium and may include program instructions to perform particular tasks.

A computer program product may include one or more computer-executable components which, when the program is run, are configured to carry out some example embodiments. The one or more computer-executable components may be at least one software code or portions of code. Modifications and configurations required for implementing functionality of an example embodiment may be performed as routine(s), which may be implemented as added or updated software routine(s). In one example, software routine(s) may be downloaded into the apparatus.

As an example, software or a computer program code or portions of code may be in a source code form, object code form, or in some intermediate form, and it may be stored in some sort of carrier, distribution medium, or computer readable medium, which may be any entity or device capable of carrying the program. Such carriers may include a record medium, computer memory, read-only memory, photoelectrical and/or electrical carrier signal, telecommunications signal, and/or software distribution package, for example. Depending on the processing power needed, the computer program may be executed in a single electronic digital computer or it may be distributed amongst a number of computers. The computer readable medium or computer readable storage medium may be a non-transitory medium.

In other example embodiments, the functionality may be performed by hardware or circuitry included in an apparatus (e.g., apparatus 20), for example through the use of an application specific integrated circuit (ASIC), a programmable gate array (PGA), a field programmable gate array (FPGA), or any other combination of hardware and software. In yet another example embodiment, the functionality may be implemented as a signal, such as a non-tangible means that can be carried by an electromagnetic signal downloaded from the Internet or other network.

According to an example embodiment, an apparatus, such as a node, device, or a corresponding component, may be configured as circuitry, a computer or a microprocessor, such as single-chip computer element, or as a chipset, which may include at least a memory for providing storage capacity used for arithmetic operation(s) and/or an operation processor for executing the arithmetic operation(s).

Example embodiments described herein apply equally to both singular and plural implementations, regardless of whether singular or plural language is used in connection with describing certain embodiments. For example, an embodiment that describes operations of a single system (or single instances of elements of the system) equally applies to embodiments that include multiple instances of the system (or multiple instances of elements of the system), and vice versa.

Although some embodiments were described in the context of an audio output device, certain embodiments apply equally to testing of audio input devices. For example, the DUT 100 may be a microphone. In this case, operations or elements of the system may be modified. For example, testing base 110 may include speakers rather than microphones 112. In addition, the audio captured by the DUT 100, rather than the audio output from the DUT 100, may be tested.

One having ordinary skill in the art will readily understand that the example embodiments as discussed above may be practiced with operations in a different order, and/or with hardware elements in configurations which are different than those which are disclosed. Therefore, although some embodiments have been described based upon these example preferred embodiments, it would be apparent to those of skill in the art that certain modifications, variations, and alternative constructions would be apparent, while remaining within the spirit and scope of example embodiments.

1. A method, comprising:
determining, by a system, a wireless address of a device under testing (DUT),
wherein the DUT is an audio output device;
determining, by the system, an array of tests for the DUT based on information associated with the DUT;
providing, by the system, an indication that the DUT can be placed on a testing base for testing or that the system is ready to perform the array of tests;
establishing, by the system, an audio connection with the DUT in association with the DUT being placed on the testing base or the system being ready to perform the array of tests;
performing, by the system, the array of tests by providing a set of instructions associated with causing the DUT or a speaker device of the system to output audio; and
determining, by the system and in association with performing the array of tests, a result of the array of tests.

2. The method according to claim 1, further comprising:
receiving, prior to determining the wireless address, a portion of the information associated with the DUT from a reader device of the system, wherein the portion of the information is from a tag associated with the DUT; and
determining another portion of the information from a database based on the portion of the information from the tag.

3. The method according to claim 1, further comprising:
providing, for display, a set of instructions associated with causing the DUT to be moved into communicative proximity of a near-field communication (NFC) device prior to determining the wireless address of the DUT; and
wherein determining the wireless address further comprises:
determining the wireless address via the NFC device after providing the set of instructions for display.

4. The method according to claim 1, wherein the information associated with the DUT identifies at least one of:
a make of the DUT,
a model of the DUT,
an age of the DUT,
a capability of the DUT,
a quantity of hours of audio output of the DUT, or
an amount of time since the DUT was subject to a particular test.

5. The method according to claim 1, wherein establishing the audio connection comprises at least one of:
providing the wireless address and a set of instructions to a transceiver of the system,
wherein the set of instructions is associated with causing the transceiver to establish a wireless audio connection with the DUT using the wireless address, or
actuating a robotic arm of the system to cause an audio cable to be coupled with an audio jack of the DUT to establish a wired audio connection with the DUT.

6. The method according to claim 1, wherein the array of tests includes at least one of:
a test of a volume range of the DUT,
a test of a frequency range of the DUT,
a test of whether speakers of the DUT are operational,
a test of a button or other control of the DUT,
a test of a mechanical hinge, swivel, or adjuster of the DUT,
a test of a power jack of the DUT, or
a test of an audio jack of the DUT.

7. The method according to claim 1, wherein performing the array of tests further comprises:
providing another set of instructions associated with causing the DUT to operate in a particular mode based on whether the set of instructions is associated with causing the DUT or the speaker device to output audio.

8. A system, comprising:
one or more devices that comprise at least one of:
at least one client device;
at least one near-field communication (NFC) device;
at least one speaker device;
at least one server device; and
at least one testing base that comprises at least one microphone and at least one transceiver;
wherein the one or more devices are configured to cause the system at least to:
determine a wireless address of a device under testing (DUT),
wherein the DUT is an audio output device;
determine an array of tests for the DUT based on information associated with the DUT;
provide an indication that the DUT can be placed on a testing base for testing or that the system is ready to perform the array of tests;
establish an audio connection with the DUT in association with the DUT being placed on the testing base or the system being ready to perform the array of tests;
perform the array of tests by providing a set of instructions associated with causing the DUT or the at least one speaker device of the system to output audio; and
determine, in association with performing the array of tests, a result of the array of tests.

9. The system according to claim 8, wherein the one or more devices, when causing the system to perform the array of tests, further cause the system to:
provide the set of instructions to cause the DUT or the at least one speaker device to output the audio at a particular frequency range or volume.

10. The system according to claim 8, wherein the one or more devices, when causing the system to perform the array of tests, further cause the system to:
provide another set of instructions associated with causing the DUT to operate in a particular mode based on whether the set of instructions is associated with causing the DUT or the at least one speaker device to output audio.

11. The system according to claim 10, wherein the particular mode comprises at least one of:
a noise canceling mode,
an ambient sound mode, or
a bass boosting mode.

12. The system according to claim 8, wherein the one or more devices, when causing the system to determine the result of the array of tests, further cause the system to:
determine a score for at least one test of the array of tests or for the DUT; and
determine a pass or failure of the array of tests or the DUT based on the score.

13. The system according to claim 8, wherein the one or more devices are configured to further cause the system to:
perform one or more actions based on the result of the array of tests.

14. The system according to claim 13, wherein the one or more actions include at least one of:
providing the result for display,
outputting an indication based on the result,
scheduling the DUT for recycling or refurbishing,
generating a report that identifies one or more components of the DUT to be recycled or refurbished, or
causing the DUT to be transported to an area of a facility associated with shipping, packaging, recycling, or refurbishing the DUT.

15. A non-transitory computer readable medium comprising program instructions for causing a system to perform at least the following:
determining a wireless address of a device under testing (DUT),
wherein the DUT is an audio output device;
determining an array of tests for the DUT based on information associated with the DUT;
providing an indication that the DUT can be placed on a testing base for testing or that the system is ready to perform the array of tests;
establishing an audio connection with the DUT in association with the DUT being placed on the testing base or the system being ready to perform the array of tests;
performing the array of tests by providing a set of instructions associated with causing the DUT or a speaker device of the system to output audio; and
determining, in association with performing the array of tests, a result of the array of tests.

16. The non-transitory computer readable medium according to claim 15, wherein the program instructions further cause the system to perform at least the following:
receiving, prior to determining the wireless address, a portion of the information associated with the DUT from a reader device of the system, wherein the portion of the information is from a tag associated with the DUT; and
determining another portion of the information from a database based on the portion of the information from the tag.

17. The non-transitory computer readable medium of claim 15, wherein the program instructions, when causing the system establish the connection, further cause the system to perform at least the following:
providing the wireless address and a set of instructions to a transceiver of the system,
wherein the set of instructions is associated with causing the transceiver to establish a wireless connection with the DUT, or
actuating a robotic arm of the system to cause an audio cable to be coupled with an audio jack of the DUT to establish a wired connection with the DUT.

18. The non-transitory computer readable medium of claim 15, wherein the array of tests includes at least one of:
a test of a volume range of the DUT,
a test of a frequency range of the DUT,
a test of whether speakers of the DUT are operational,
a test of a button or other control of the DUT,
a test of a mechanical hinge, swivel, or adjuster of the DUT,
a test of a power jack of the DUT, or
a test of an audio jack of the DUT.

19. The non-transitory computer readable medium of claim 15, wherein the program instructions, when causing the system to determine the result of the array of tests, further cause the system to perform at least the following:
determining a score for at least one of the array of tests or the DUT; and
determining a pass or failure of the array of tests or the DUT based on the score.

20. The non-transitory computer readable medium of claim 15, wherein the program instructions further cause the system to perform at least the following:
performing one or more actions based on the result of the array of tests.
